(19) United States
(12) Patent Application Publication
(10) Pub. No.: US 2014/0251393 A1
(43) Pub. Date: Sep. 11, 2014

(54) APPLICATION LIQUID APPLICATION APPARATUS AND APPLICATION LIQUID APPLICATION METHOD

(71) Applicant: Kabushiki Kaisha Toshiba, Minato-ku (JP)

(72) Inventor: Eiji YONEDA, Mie-ken (JP)

(73) Assignee: Kabushiki Kaisha Toshiba, Minato-ku (JP)

(21) Appl. No.: 13/972,018

(22) Filed: Aug. 21, 2013

(30) Foreign Application Priority Data
Mar. 8, 2013 (JP) 2013-047310

(51) Int. Cl. G03F 7/16

(52) U.S. Cl. CPC G03F 7/16
USPC 134/56 R

(57) ABSTRACT

According to one embodiment, an application liquid application apparatus includes: a support stage having a rotation mechanism; and an application liquid discharge module configured to discharge an application liquid onto a surface of a substrate mounted on the support stage along on a rotation axis of the support stage. The application liquid discharge module including: a nozzle configured to discharge the application liquid toward the surface of the substrate; at least one application liquid supply line configured to supply the application liquid to the nozzle; a valve control unit; and a valve control data memory unit. The application liquid supply line including: a supply tube configured to supply the application liquid to the nozzle; and a maximum flow rate adjustment module configured to adjust a maximum flow rate of the application liquid in the supply tube; a first valve; and at least one second valve.

### CROSS-REFERENCE TO RELATED APPLICATIONS

This application is based upon and claims the benefit of priority from Japanese Patent Application No. 2013-047310, filed on Mar. 8, 2013; the entire contents of which are incorporated herein by reference.

### FIELD

Embodiments described herein relate generally to an application liquid application apparatus and an application liquid application method.

### BACKGROUND

In a lithography process among semiconductor manufacturing processes, a photoresist liquid is discharged onto a substrate rotating, and the photoresist liquid is diffused on the surface of the substrate by the centrifugal force due to the rotation of the substrate. Thereby, the photoresist liquid is applied onto the surface of the substrate. As the substrate, a semiconductor substrate, a glass substrate, a sapphire substrate, any other insulating substrate, etc. are used. The lithography process is used not only for methods for manufacturing a semiconductor device but also for methods for manufacturing a photomask, a liquid crystal display device, an optical disk, etc. That is, a photoresist liquid is applied onto a substrate such as a glass substrate for a photomask, a glass substrate for a liquid crystal display device, and a substrate for an optical disk in a similar way to the manufacturing process of a semiconductor device. In the lithography process, in addition to the photoresist liquid, also chemical liquids such as a developer and a rinse are applied onto the surface of the substrate. A reduction in the amount of these chemical liquids discharged onto the substrate is desired in order to reduce manufacturing costs. In particular, since the photoresist liquid is expensive, a reduction in the amount of photoresist liquid used is desired in order to reduce manufacturing costs. However, when the amount of photoresist liquid discharged onto the substrate is reduced, the photoresist liquid will not be uniformly applied onto the surface of the substrate. The same goes for other chemical liquids. An application liquid application apparatus and an application liquid application method are desired that can apply a photoresist liquid uniformly onto the surface of a substrate by a small amount of photoresist liquid discharged.

### BRIEF DESCRIPTION OF THE DRAWINGS

FIG. 1 is a schematic configuration diagram showing an overview of a main portion of an application liquid application apparatus according to a first embodiment;

FIG. 2 is a profile of a discharge rate of an application liquid discharged onto a surface of a substrate by the application liquid application apparatus according to the first embodiment to time;

FIG. 3 is another profile of the discharge rate of the application liquid discharged onto the surface of the substrate by the application liquid application apparatus according to the first embodiment to time;

FIG. 4 is a diagram describing an application liquid application method using the application liquid application apparatus according to the first embodiment;

FIG. 5 is a diagram describing an application liquid application method using an application liquid application apparatus according to a comparative example; and

FIG. 6 is a diagram of a schematic comparison of film thickness uniformity of photoresist films according to the first embodiment and the comparative example.

### DETAILED DESCRIPTION

In general, according to one embodiment, an application liquid application apparatus includes: a support stage for a substrate to be mounted on, the support stage having a rotation mechanism; and an application liquid discharge module configured to discharge an application liquid onto a surface of a substrate mounted on the support stage along on a rotation axis of the support stage. The application liquid discharge module including: a nozzle configured to discharge the application liquid toward the surface of the substrate; at least one application liquid supply line configured to supply the application liquid to the nozzle; a valve control unit; and a valve control data memory unit. The application liquid supply line including: a supply tube configured to supply the application liquid to the nozzle; and a maximum flow rate adjustment module configured to adjust a maximum flow rate of the application liquid in the supply tube; a first valve provided in a portion of the supply tube between the maximum flow rate adjustment module and the nozzle, the first valve having a first state in which supply of the application liquid to the nozzle is interrupted in the supply tube and a second state in which the application liquid is supplied to the nozzle in the supply tube, the first state and the second state being switchable by a signal from the valve control unit based on valve control data stored in the valve control data memory unit; and at least one second valve provided in a portion of the supply tube between the first valve and the maximum flow rate adjustment module, the second valve having a third state in which a flow rate of the application liquid in the supply tube is decreased and a fourth state in which a flow rate of the application liquid in the supply tube is maintained, the third state and the fourth state being switchable independently of the first valve by a signal from the valve control unit based on valve control data stored in the valve control data memory unit.

Hereinbelow, embodiments are described with reference to the drawings. The drawings used in the description of the embodiments are schematic for easier description; and in the actual practice, the configurations, dimensions, magnitude relationships, etc. of components in the drawings are not necessarily the same as those illustrated in the drawings and may be appropriately altered to the extent that the effect of the embodiments is obtained. The embodiments are described using a lithography process of a semiconductor manufacturing process as an example, but the embodiments may be applied also to manufacturing processes of a photomask, a liquid crystal display device, an optical disk, etc. The embodiments are described using, as an example, the case where the application liquid is a photoresist liquid, but the embodiments may be applied also to the case where the application liquid is a chemical liquid such as a developer and a rinse.

### First Embodiment

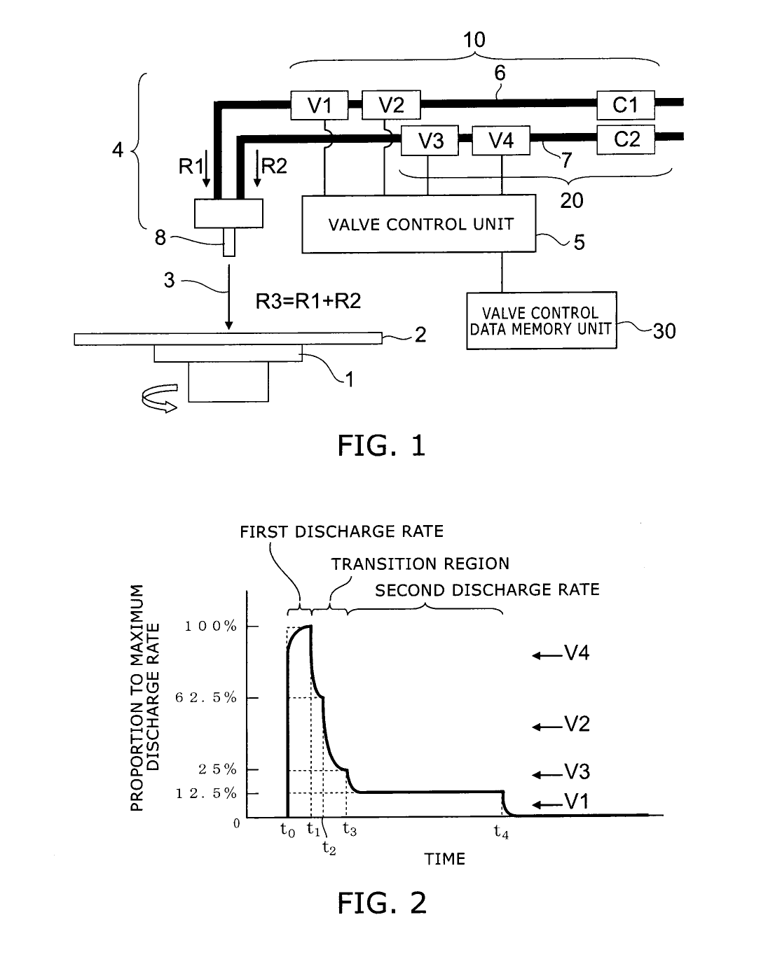

An application liquid application apparatus and an application liquid application method according to a first embodiment will now be described using FIG. 1 to FIG. 6.

FIG. 1 is a schematic configuration diagram showing an overview of a main portion of an application liquid application apparatus according to the embodiment.

FIG. 2 is a profile of the discharge rate of an application liquid discharged onto the surface of a substrate by the application liquid application apparatus according to the embodiment to time.

FIG. 3 is another profile of the discharge rate of the application liquid discharged onto the surface of the substrate by the application liquid application apparatus according to the embodiment to time.

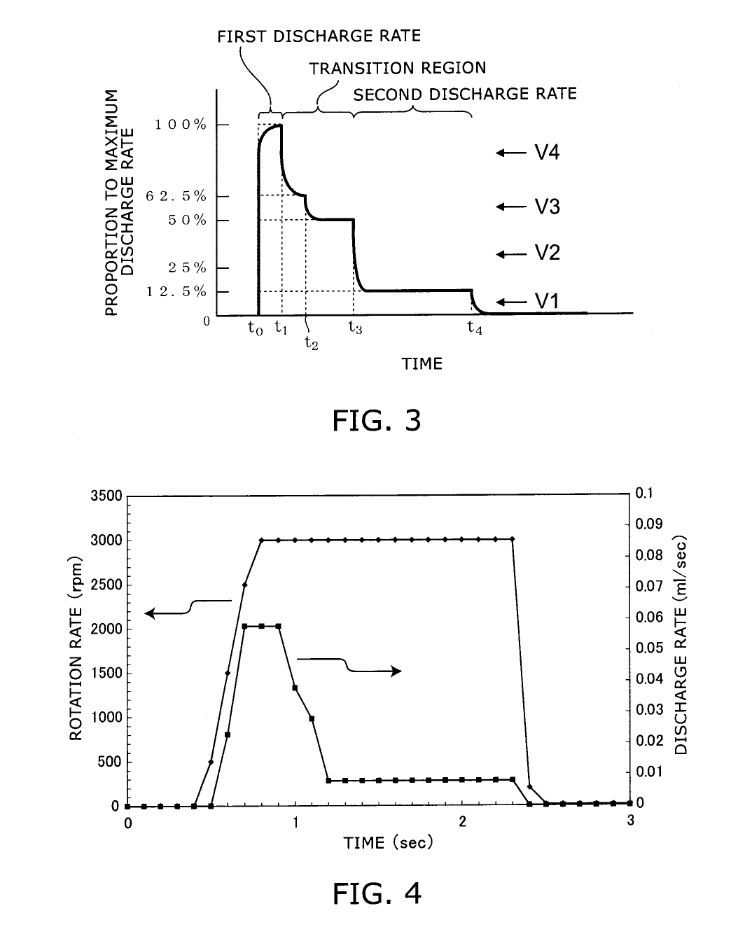

FIG. 4 is a diagram describing an application liquid application method using the application liquid application apparatus according to the embodiment.

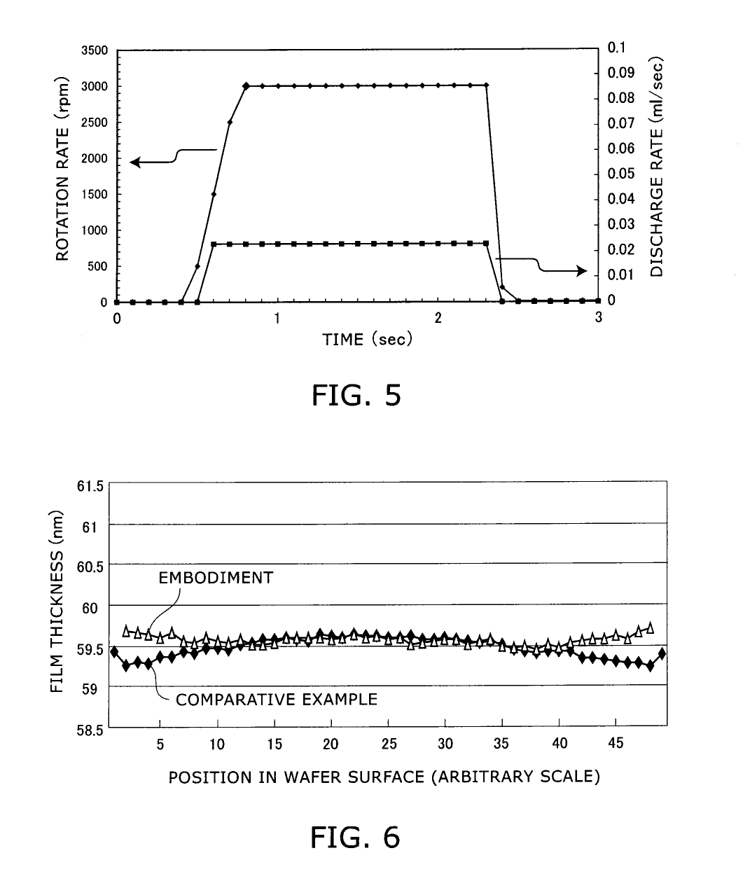

FIG. 5 is a diagram describing an application liquid application method using an application liquid application apparatus according to a comparative example.

FIG. 6 is a diagram of a schematic comparison of the film thickness uniformity of photoresist films according to the embodiment and the comparative example.

As shown in FIG. 1, the application liquid application apparatus according to the embodiment includes a support stage 1 for a substrate 2 to be mounted on and an application liquid discharge module 4. The support stage 1 has a rotation mechanism, and the rotational speed is controlled by a not-shown rotation control unit. The application liquid discharge module 4 discharges an application liquid 3 onto the surface of the substrate 2 mounted on the support stage 1.

The application liquid discharge module 4 includes a nozzle 8, at least one application liquid supply line 10, a valve control unit 5, and a valve control data memory unit 30. The application liquid application apparatus according to the embodiment includes, as an example, two application liquid supply lines of the application liquid supply line 10 and an application liquid supply line 20. The application liquid supply line 10 and the application liquid supply line 20 are connected in parallel to the nozzle 8. The nozzle 8 discharges the application liquid 3 toward the surface of the substrate 2.

The application liquid supply line 10 and the application liquid supply line 20 supply the application liquid 3 to the nozzle 8. The application liquid supply line 10 includes a supply tube 6 that supplies the application liquid 3 to the nozzle 8, a maximum flow rate adjustment module C1 that adjusts the maximum flow rate of the application liquid 3 in the supply tube 6, a first valve V1, and a second valve V2.

The maximum flow rate adjustment module C1 that adjusts the maximum flow rate of the application liquid 3 in the supply tube 6 is, for example, a pump that supplies the application liquid 3 to the supply tube 6 from a not-shown replenishment container filled with the application liquid 3. However, it is not limited thereto. Any module that can control the flow rate of the application liquid 3 in the supply tube 6 may be used, and for example, a valve may be used that is provided between the replenishment container and the supply tube 6 and controls the flow rate of the application liquid 3 by the degree of opening of the valve, which is the degree at which the valve is open.

The first valve V1 is provided in a portion of the supply tube 6 between the maximum flow rate adjustment module C1 and the nozzle 8. The first valve V1 has a first state and a second state that are switched by a signal from the valve control unit 5 based on valve control data stored in the valve control data memory unit 30. When the first valve V1 is in the first state, the first valve V1 is fully closed, and the supply of the application liquid 3 to the nozzle 8 is interrupted in the supply tube 6. When the first valve is in the second state, the first valve V1 is fully open; and assuming that the second valve V2 described later is not present, the application liquid 3 is supplied to the nozzle 8 in the supply tube 6 at the maximum flow rate adjusted by the maximum flow rate adjustment module C1. That is, when the first valve is in the second state, the flow rate of the application liquid 3 in the supply tube 6 is maintained.

The second valve V2 has, independently of the first valve V1, a third state and a fourth state that are switched by a signal from the valve control unit 5 based on valve control data stored in the valve control data memory unit 30. When the second valve is in the third state, the flow rate of the application liquid in the supply tube 6 is decreased by the second valve V2 in accordance with the degree of opening of the valve. When the second valve is in the fourth state, the second valve is fully open; and assuming that the first valve V1 described above is not present, the application liquid 3 is supplied to the nozzle 8 from the supply tube 6 at the maximum flow rate adjusted by the maximum flow rate adjustment module C1. In other words, when the second valve is in the fourth state, the flow rate of the application liquid 3 in the supply tube 6 is maintained when the first valve V1 described above is not present. That is, the flow rate of the application liquid 3 in the supply tube 6 is low when the second valve V2 is in the third state, and the flow rate of the application liquid 3 in the supply tube 6 is high when the second valve is in the fourth state.

Similarly to the application liquid supply line 10, also the application liquid supply line 20 includes a supply tube 7 that supplies the application liquid 3 to the nozzle 8, a maximum flow rate adjustment module C2 that adjusts the maximum flow rate of the application liquid 3 in the supply tube 7, a first valve V3, and a second valve V4. The maximum flow rate adjustment module C2 is similar to the maximum flow rate adjustment module C1 of the application liquid supply line 10, and works similarly. The first valve V3 and the second valve V4 are similar to the first valve V1 and the second valve V2, respectively, of the first application liquid supply line 10, and work similarly.

The application liquid discharge module 4 of the application liquid application apparatus according to the embodiment includes the first application liquid supply line 10 and the second application liquid supply line 20 in parallel as described above. The first valve V1 and the second valve V2 provided in the first application liquid supply line 10 and the first valve V3 and the second valve V4 provided in the second application liquid supply line 20 are independently controlled by the valve control unit 5. Therefore, the first valve V1 of the first application liquid supply line 10 and the first valve V3 of the second application liquid supply line 20 can independently enter the first state or the second state. Similarly, the second valve V2 of the first application liquid supply line 10 and the second valve V4 of the second application liquid supply line 20 can independently enter the third state or the fourth state.

In the first application liquid supply line 10, the flow rate R1 of the application liquid can be discretely changed from zero to the maximum flow rate adjusted by the maximum flow rate adjustment module C1 by setting the first valve V1 to the first state or the second state and the second valve V2 to the third state or the fourth state. Similarly, in the second application liquid supply line 20, the flow rate R2 of the application liquid can be discretely changed from zero to the maximum flow rate adjusted by the maximum flow rate adjustment module C2 by setting the first valve V3 to the first state or the second state and the second valve V4 to the third state or the fourth state.

The application liquid 3 supplied by the first application liquid supply line 10 and the application liquid 3 supplied by the second application liquid supply line 20 join together and are discharged from the nozzle 8. The discharge rate R3 of the application liquid discharged from the nozzle 8 is the sum of the flow rate R1 of the application liquid 3 of the first application liquid supply line 10 and the flow rate R2 of the application liquid 3 of the second application liquid supply line 20.

The combination of the states of the valves V1 to V4 of the first application liquid supply line 10 and the second application liquid supply line 20 may be changed with time. Thereby, a profile of the discharge rate of the application liquid discharged from the application liquid discharge module 4 to time can be arbitrarily created. Table 1 shows an example in which the states of the valves V1 to V4 are changed with time.

TABLE 1

| Time | t₀ | t₁ | t₂ | t₃ | t₄ |
|---|---|---|---|---|---|
| V1 | ON | ON | ON | ON | OFF |
| V2 | HIGH | HIGH | LOW | LOW | LOW |
| V3 | ON | ON | ON | OFF | OFF |
| V4 | HIGH | LOW | LOW | LOW | LOW |
| Proportion | 100% | 62.5% | 25% | 12.5% | 0% |

Here, for the first valve V1 of the first application liquid supply line 10 and the first valve V3 of the second application liquid supply line, the first state in which the valve is fully closed is expressed as OFF, and the second state in which the valve is fully open is expressed as ON. For the second valve V2 of the first application liquid supply line 10 and the second valve V4 of the second application liquid supply line, the third state in which the valve is open at a prescribed degree of opening is expressed as LOW, and the fourth state in which the valve is fully open is expressed as HIGH. The degree of opening of the valve being 0% refers to fully closed, and the degree of opening of the valve being 100% refers to fully open.

For easier description, it is assumed that the maximum flow rate of the first application liquid supply line 10 adjusted by the maximum flow rate adjustment module C1 and the maximum flow rate of the second application liquid supply line 20 adjusted by the maximum flow rate adjustment module C2 are the same flow rate. Furthermore, it is assumed that when the first valve V1 of the first application liquid supply line 10 is in the ON state and the second valve V2 is switched from the HIGH state to the LOW state, the flow rate R1 of the application liquid 3 of the first supply line decreases by 75% of the maximum flow rate in the first application liquid supply line 10. The same goes for the second valve V4 of the second application liquid supply line 20. That is, when the second valve V2 or V4 is singly switched from the HIGH state to the LOW state, the discharge rate R3 of the application liquid discharged from the nozzle 8 decreases by 37.5% of the maximum discharge rate of the application liquid 3 discharged from the nozzle 8.

In the first application liquid supply line, when the second valve V2 is in the LOW state and the first valve V1 is switched from the ON state to the OFF state, the first application liquid supply line 10 is interrupted; thus, the flow rate R1 of the application liquid 3 of the first application liquid supply line decreases by the remaining 25% of the maximum flow rate of the first application liquid supply line 10. The same goes for the first valve V3 of the second application liquid supply line 20. That is, when the second valve V2 of the first application liquid supply line 10 is in the LOW state and the first valve V1 is switched from the ON state to the OFF state, the discharge rate R3 of the application liquid 3 discharged from the nozzle 8 decreases by 12.5% of the maximum discharge rate of the application liquid 3 discharged from the nozzle 8. Similarly, when the second valve V4 of the second application liquid supply line 20 is in the LOW state and the first valve V3 is switched from the ON state to the OFF state, the discharge rate R3 of the application liquid 3 discharged from the nozzle 8 decreases by 12.5% of the maximum discharge rate of the application liquid 3 discharged from the nozzle 8.

By producing the state of each of the valves V1 to V4 for each time as shown in Table 1, a profile of the discharge rate to time of the application liquid 3 discharged from the application liquid supply module 4 onto the surface of the substrate 2 is obtained as shown in FIG. 2. The horizontal axis of the graph is time, and the vertical axis is the discharge rate of the application liquid 3 discharged from the nozzle 8. The discharge rate is expressed as the proportion of the discharge rate of the application liquid discharged from the nozzle 8 to the maximum discharge rate. The proportion of the discharge rate of the application liquid discharged from the nozzle 8 to the maximum discharge rate is shown also in Table 1. The maximum discharge rate of the application liquid 3 discharged from the nozzle 8 is the sum of the maximum flow rate of the application liquid 3 in the first application liquid supply line 10 and the maximum flow rate of the application liquid 3 in the second application liquid supply line 20, and is twice the maximum flow rate of the application liquid in the first application liquid supply line 10.

Here, the amount shown by the bar graph of the broken line shows the amount of decrease in the discharge rate of the application liquid 3 discharged from the nozzle 8 when the states of the valves V1 to V4 of the first application liquid supply line 10 and the second application liquid supply line 20 are changed. The graph of the solid line is the change with time, that is, the profile to time of the discharge rate of the application liquid 3 actually discharged from the nozzle 8 by the state change of the valves V1 to V4.

As shown in Table 1, at time tₒ, all of the valves V1 to V4 of the application liquid supply module 4 of the application liquid application apparatus according to the embodiment are in the fully open state. That is, both the first valve V1 of the first application liquid supply line 10 and the first valve V3 of the second application liquid supply line 20 are in the ON state, and both the second valve V2 of the first application liquid supply line and the second valve V4 of the second application liquid supply line 20 are in the HIGH state. The discharge rate of the application liquid 3 at this time is referred to as a first discharge rate. In the initial state before time tₒ, at least both the valve V1 and the valve V3 are in the fully closed state. The valve V2 and the valve V4 are in the HIGH state or the LOW state.

Next, at time t₁, the second valve V4 of the second application liquid supply line 20 is switched from the HIGH state to the LOW state. The setting of the discharge rate of the application liquid 3 discharged from the nozzle 8 becomes 62.5% of the maximum discharge rate as shown in Table 1 and FIG. 2. Thus, the state where the discharge rate of the application liquid 3 discharged from the nozzle 8 is the first discharge rate of 100% is maintained for a time of (t₁−t₀). The application liquid 3 is discharged from the application liquid discharge module 4 onto the surface of the substrate 2 at the first discharge rate for a period of a first time of (t₁−t₀). The discharge rate of the application liquid 3 discharged from the actual nozzle 8 rises steeply at time t₀, but reaches the first discharge rate a little later.

Next, at time t₂, the second valve V2 of the first application liquid supply line 10 is switched from the HIGH state to the LOW state. The setting of the discharge rate of the application liquid 3 discharged from the nozzle 8 becomes 25% of the maximum discharge rate. That is, the state where the discharge rate of the application liquid 3 discharged from the nozzle 8 is 62.5% is maintained for a time of (t₂−t₁). The discharge rate of the application liquid 3 discharged from the actual nozzle 8 rises steeply at time t₁, but reaches the discharge rate of 62.5% of the maximum discharge rate a little later.

Next, at time t₃, the first valve V3 of the second application liquid supply line 20 is switched from the ON state to the OFF state. The setting of the discharge rate of the application liquid 3 discharged from the nozzle 8 becomes 12.5% of the maximum discharge rate, which is a second discharge rate. That is, the state where the discharge rate of the application liquid 3 discharged from the nozzle 8 is 25% is maintained for a time of (t₃−t₂). The discharge rate of the application liquid 3 discharged from the actual nozzle 8 rises steeply at time t₂, but reaches 25% of the maximum discharge rate a little later. The profile of the application rate of the application liquid 3 discharged from the nozzle 8 to time has a transition region where a transition occurs from the first discharge rate (100%) to the second discharge rate (12.5%). That is, in the transition region, the application liquid 3 is discharged from the application liquid discharge module 4 onto the surface of the substrate 2 for a period of a second time of (t₃−t₁) while transitioning from the first discharge rate to the second discharge rate.

Next, at time t₄, the first valve V1 of the first application liquid supply line 10 is switched from the ON state to the OFF state. The setting of the discharge rate of the application liquid 3 discharged from the nozzle 8 changes from the second discharge rate to zero. That is, the state where the discharge rate of the application liquid 3 discharged from the nozzle 8 is the second discharge rate of 12.5% is maintained for a time of (t₄−t₃). The application liquid 3 is discharged from the application liquid discharge module 4 onto the surface of the substrate 2 at the second discharge rate for a period of a third time of (t₄−t₃). The discharge rate of the application liquid 3 discharged from the actual nozzle 8 rises steeply at time t₄, but becomes zero a little later.

The profile of the discharge rate of the application liquid 3 discharged from the application liquid supply module 4 to time can be altered to an arbitrary profile by, as shown in FIG. 2, appropriately altering the time setting of t₁ to t₄, the degree of opening in the third state (the LOW state) of the second valves V2 and V4, the maximum flow rate of the application liquid 3 in the first application liquid supply line and the second application liquid supply line adjusted by the maximum flow rate adjustment module C1 and C2, etc.

Next, Table 2 and FIG. 3 show another setting example of the profile of the discharge rate of the application liquid 3 discharged from the application liquid supply module 4 onto the surface of the substrate 2 to time, which is obtained by using the application liquid application apparatus according to the embodiment. As shown in Table 2, in this setting example, the time when the second valve V2 of the first application liquid supply line 10 is switched from the HIGH state to the LOW state and the time when the first valve V3 of the second application liquid supply line 20 is switched from the ON state to the OFF state are exchanged. That is, at time t₂, the first valve V3 of the second application liquid supply line 20 is switched from the ON state to the OFF state earlier than the second valve V2 of the first application liquid supply line 10. After that, at time t₃, the second valve V2 of the first application liquid supply line 10 is switched from the HIGH state to the LOW state. In this point, this setting example of the discharge rate of the application liquid 3 of the application liquid supply module 4 differs from the setting example described above.

TABLE 2

| Time | t₀ | t₁ | t₂ | t₃ | t₄ |
|---|---|---|---|---|---|
| V1 | ON | ON | ON | ON | OFF |
| V2 | HIGH | HIGH | HIGH | LOW | LOW |
| V3 | ON | ON | OFF | OFF | OFF |
| V4 | HIGH | LOW | LOW | LOW | LOW |
| Proportion | 100% | 62.5% | 50% | 12.5% | 0% |

As shown in Table 2, by setting the valves V1 to V4 for each time, a profile of the discharge rate of the application liquid 3 discharged from the application liquid supply module 4 to time is obtained as shown in FIG. 3. In the profile of the discharge rate of the application liquid 3 of FIG. 3, the transition from the first discharge rate to the second discharge rate is gentler than in the profile of the discharge rate of the application liquid 3 of FIG. 2.

The application liquid application apparatus according to the embodiment includes the first application liquid supply line 10 and the second application liquid supply line 20 in the application liquid supply module 4 as described above. The embodiment is not limited thereto, and the application liquid supply module 4 may include a plurality of application liquid supply lines.

The application liquid application apparatus according to the embodiment includes one second valve V2 (or V4) for one application liquid supply line as described above. However, the embodiment is not limited thereto. One application liquid supply line may include a plurality of second valves V2 in series.

In the application liquid application apparatus, when the application liquid supply module 4 includes a plurality of application liquid supply lines and each application liquid supply line includes a plurality of second valves V2 (or V4) connected in series between the first valve V1 (or V3) and the maximum flow rate setting module C1 (or C2), the profile shown in FIG. 2 or FIG. 3 of the discharge rate of the application liquid 3 discharged from the application liquid supply module 4 to time can be made still finer forms. In particular, the discharge rate of the application liquid 3 discharged from the application liquid supply module 4 can be made to transition from the first discharge rate to the second discharge rate continuously and smoothly, not discretely. Thereby, the application liquid 3 can be discharged from the application liquid supply module 4 onto the surface of the substrate 2 with good efficiency while eliminating wastage.

Next, a method for applying an application liquid onto the surface of the substrate 2 using the application liquid application apparatus according to the embodiment is described with reference to FIG. 4 to FIG. 6. The application liquid application method is described using, as an example, the case where a photoresist is used as the application liquid.

As shown in FIG. 4, the application liquid application apparatus according to the embodiment is used to apply a photoresist 3 onto the surface of the substrate 2 mounted on the support stage 1 rotating.

In a first process, the support stage 1 is rotated from when, for example, 0.4 seconds has elapsed from the start of processing. The rotation of the support stage is rapidly accelerated so that the rotational speed of the support stage becomes a first rotational speed, for example, 3000 rpm. In the embodiment, the rotational speed of the support stage 1 reaches 3000 rpm in 0.4 seconds. The first rotational speed of the support stage is determined in accordance with the film thickness of the photoresist 3 applied onto the surface of the substrate 2, and is determined between, for example, 2500 rpm and 4000 rpm.

Here, in the period from when the support stage 1 starts to rotate to when it reaches the first rotational speed, for example at the time when 0.5 seconds has elapsed from the start of processing, the photoresist 3 begins to be discharged from the application liquid discharge module 4 onto the surface of the substrate 2. As described above, by setting the first valves and the second valves V1 to V4 of the application liquid discharge module 4 to fully open, the photoresist 3 is discharged from the application liquid discharge module 4 onto the surface of the substrate 2. The discharge rate of the photoresist 3 reaches 0.058 ml/second, which is the first discharge rate, in approximately 0.2 seconds. After that, the discharge rate of the photoresist 3 is kept at the first discharge rate for 0.2 seconds in a period of 0.9 seconds from the start of processing. The photoresist 3 is discharged onto the surface of the substrate 2 by the application liquid discharge module 4 at the first discharge rate for a period of the first time (0.4 seconds).

Here, the photoresist 3 preferably begins to be discharged with a rotational speed of the support stage 1 of 2000 rpm or less. If the photoresist 3 is dropped onto the surface of the substrate 2 rotating at a rotational speed not less than the above speed, the photoresist 3 is scattered off the surface of the substrate 2 because the centrifugal force is too strong. In the embodiment, the photoresist 3 is dropped onto the surface of the substrate 2 when the rotational speed of the support stage 1 has become, for example, approximately 500 rpm.

Since the rotational speed of the support stage 1 has been rapidly accelerated toward the first rotational speed, the photoresist 3 spreads rapidly on the surface of the substrate 2 toward the outer periphery. At this time, if the discharge rate of the photoresist 3 is too low, the supply balance of the photoresist 3 is broken on the surface of the substrate 2 and application unevenness of the photoresist 3 is caused. In the first process, the photoresist 3 is discharged from the application liquid supply module 4 onto the surface of the substrate 2 at the first discharge rate sufficient for the photoresist 3 to cover the surface of the substrate 2 uniformly.

Next, in a second process, while the rotational speed of the support stage 1 is kept at the first rotational speed mentioned above, the photoresist 3 is discharged onto the surface of the substrate 2 while the discharge rate of the photoresist 3 discharged from the application liquid supply module 4 is transitioned from the first discharge rate to the second discharge rate in the second time. In the embodiment, the second discharge rate is 0.008 ml/second, for example.

Specifically, when 0.9 seconds has elapsed from the start of processing, the second valve V4 of the second application liquid supply line 20 of the application liquid supply module 4 is switched from the HIGH state to the LOW state. When 1.0 second has elapsed from the start of processing, the first valve V3 of the second application liquid supply line 20 is switched from the ON state to the OFF state. When 1.1 seconds has elapsed from the start of processing, the second valve V2 of the first application liquid supply line 10 is switched from the HIGH state to the LOW state. By the above change of the valve state, the photoresist 3 is discharged onto the surface of the substrate 2 while the discharge rate of the photoresist 3 transitions from the first discharge rate to the second discharge rate in the second time (0.2 seconds).

Next, in a third process, while the rotational speed of the support stage 1 is kept at the first rotational speed and the discharge rate of the photoresist 3 is kept at 0.008 ml/second, which is the second discharge rate, the photoresist 3 is discharged onto the surface of the substrate 2 for a period of the third time (1.2 seconds) until 2.3 seconds has elapsed from the start of processing. The photoresist 3 has been uniformly applied onto the entire surface of the substrate 2 in the first process, and a surface state where the photoresist 3 can spread easily has been produced. Thus, in the third process, a film can be uniformly grown on the entire surface of the substrate 2 at the second discharge rate lower than the first discharge rate.

In the first process, since the photoresist 3 diffuses less easily on the surface of the substrate 2, the discharge rate of the photoresist 3 needs to be set high. However, in the third process, the photoresist 3 discharged onto the photoresist 3 that has been applied on the surface of the substrate 2 can spread easily on the surface of the substrate 2 as described above. Thus, in order to eliminate the wastage of the photoresist, the second discharge rate of the photoresist 3 is set to the minimum necessary rate to keep uniform the film thickness of the photoresist 3 applied onto the surface of the substrate 2. This discharge rate is much lower than the first discharge rate.

Next, in a fourth process, the discharge of the photoresist 3 from the application liquid discharge module 4 is stopped, and the rotation of the support stage 1 is stopped.

In the above way, the photoresist 3 is applied onto the surface of the substrate 2 using the application liquid application apparatus according to the embodiment. In the application liquid application method using the application liquid application apparatus according to the embodiment mentioned above (hereinbelow, an application liquid application method according to the embodiment), in the first process, the photoresist 3 begins to be discharged so as to be discharged at the first discharge rate while the rotational speed of the support stage 1 is accelerated toward the first rotational speed. The first discharge rate is a discharge rate sufficient for the photoresist 3 to cover the surface of the substrate 2.

By discharging the photoresist 3 onto the surface of the substrate 2 at a high discharge rate in the initial stage, the photoresist 3 covers the surface of the substrate 2 uniformly. After that, in the second process, the discharge rate of the photoresist 3 is decreased to the second discharge rate. The second discharge rate is the minimum necessary discharge rate to keep uniform the film thickness of the photoresist applied onto the surface of the substrate 2. After that, in the third process, the film thickness of the photoresist 3 applied onto the surface of the substrate 2 is made grown uniformly while the photoresist 3 is discharged at the second discharge rate.

By supplying the photoresist 3 using the application liquid supply module 4 in this way, the photoresist 3 can be uniformly applied onto the surface of the substrate 2 by a small amount of photoresist 3 discharged.

Next, an application liquid application method according to a comparative example is described with reference to FIG. 5. Also in the application liquid application method according to the comparative example, the profile of the rotational speed of the support stage 1 to time is the same as that in the application liquid application method according to the embodiment mentioned above. Also the discharge of the photoresist 3 is started while the support stage 1 is accelerated toward the first rotational speed. However, the discharge rate of the photoresist 3 is constant at 0.023 ml/second. The profile of the discharge rate of the photoresist 3 to time in the application liquid application method according to the comparative example is different from that in the application liquid application method according to the embodiment, and does not have the process of discharging the application liquid at the first discharge rate, the process of transitioning the discharge rate of the application liquid from the first discharge rate to the second discharge rate, and the process of discharging the application liquid at the second discharge rate.

In the application liquid application method according to the comparative example, the photoresist 3 is applied onto the surface of the substrate 2 by the photoresist 3 being discharged at a constant discharge rate of the photoresist 3. The discharge rate of the photoresist 3 in this time is the minimum necessary discharge rate for the photoresist 3 to cover the surface of the substrate 2 in order to eliminate the wastage of the photoresist 3. Thus, the photoresist 3 is applied onto the surface of the substrate 2 in a state where there is unevenness in the film thickness of the photoresist 3 that has been caused in the initial stage of the application of the photoresist 3 to the surface of the substrate 2. To suppress the film thickness unevenness, it is necessary to raise the discharge rate of the photoresist. When the same amount of photoresist 3 is used, in the application liquid application method according to the comparative example, the film thickness of the photoresist 3 applied on the surface of the substrate 2 is inferior in uniformity to that in the application liquid application method according to the embodiment.

FIG. 6 shows a schematic comparison between the film thickness distribution of the photoresist applied on the surface of the substrate 2 by the application liquid application method according to the embodiment and the film thickness distribution of the photoresist applied on the surface of the substrate 2 by the application liquid application method according to the comparative example. When the same amount of photoresist is used, in the application liquid application method according to the comparative example, the film thickness of the photoresist 3 becomes small in a region of the outermost periphery of the substrate. This is because unevenness in the film thickness due to the insufficient supply of the photoresist has occurred in the initial stage of the application of the photoresist 3 to the surface of the substrate 2.

In contrast, in the application liquid application method according to the embodiment, the discharge rate of the photoresist 3 is made sufficiently high in the initial stage of the application of the photoresist 3 to the surface of the substrate 2; thus, an insufficient supply of the photoresist 3 does not occur. Therefore, unevenness in the film thickness of the photoresist 3 hardly occurs. After the photoresist 3 has covered the surface of the substrate 2, the discharge rate of the photoresist 3 for maintaining the uniformity of the film thickness of the photoresist 3 can be made significantly low as described above. Thus, in the embodiment, the second discharge rate of the photoresist 3 is set much lower than the first discharge rate. Furthermore, the time in which the photoresist 3 is discharged at the second discharge rate is longer than the time in which the photoresist 3 is discharged at the first discharge rate. Consequently, in the application liquid application method according to the embodiment, the photoresist 3 can be uniformly applied onto the surface of the substrate 2 by a small amount of photoresist discharged or used.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. An application liquid application apparatus comprising:
a support stage for a substrate to be mounted on, the support stage having a rotation mechanism; and
an application liquid discharge module configured to discharge an application liquid onto a surface of a substrate mounted on the support stage along on a rotation axis of the support stage,
the application liquid discharge module including:
a nozzle configured to discharge the application liquid toward the surface of the substrate;
at least one application liquid supply line configured to supply the application liquid to the nozzle;
a valve control unit; and
a valve control data memory unit,
the application liquid supply line including:
a supply tube configured to supply the application liquid to the nozzle;
a maximum flow rate adjustment module configured to adjust a maximum flow rate of the application liquid in the supply tube;
a first valve provided in a portion of the supply tube between the maximum flow rate adjustment module and the nozzle, the first valve having a first state in which supply of the application liquid to the nozzle is interrupted in the supply tube and a second state in which the application liquid is supplied to the nozzle in the supply tube, the first state and the second state being switchable by a signal from the valve control unit based on valve control data stored in the valve control data memory unit; and
at least one second valve provided in a portion of the supply tube between the first valve and the maximum flow rate adjustment module, the second valve having a third state in which a flow rate of the application liquid in the supply tube is decreased and a fourth state in which a flow rate of the application liquid in the supply tube is maintained, the third state and the fourth state being switchable independently of the first valve by a signal from the valve control unit based on valve control data stored in the valve control data memory unit.

2. The apparatus according to claim 1, wherein the application liquid supply line includes the second valve in plural in series along the supply tube.

3. The apparatus according to claim 2, wherein each of the plurality of second valves is switched to the third state or the fourth state independently of one another by a signal of the valve control unit.

4. The apparatus according to claim 1, wherein
the application liquid discharge module includes the application liquid supply line in plural in parallel and
the plurality of application liquid supply lines are capable of supplying the application liquid to the nozzle.

5. The apparatus according to claim 4, wherein, in the plurality of application liquid supply lines, the first valve is switchable to the first state or the second state, or the second valve is switchable to the third state or the fourth state, by a signal of the valve control unit independently of one another.

6. The apparatus according to claim 1, wherein a profile of a discharge rate of the application liquid discharged from the nozzle to time is determined by performing switching to the first state or the second state of the first valve of the application liquid supply line or switching to the third state or the fourth state of the second valve at prescribed times by the valve control unit and the valve control data memory unit.

7. The apparatus according to claim 1, wherein a first supply amount when the first valve is in the second state and the second valve is in the fourth state is higher than a second supply amount when the first valve is in the second state and the second valve is in the third state.

8. The apparatus according to claim 4, wherein, in relationships among
a third supply amount when the first valve provided in one of the application liquid supply lines is in the second state, the second valve provided in the one application liquid supply line is in the fourth state, the first valve provided in another of the application liquid supply lines aligned with the one application liquid supply line is in the second state, and the second valve provided in the other application liquid supply line is in the fourth state,
a fourth supply amount when the first valve provided in the one application liquid supply line is in the second state, the second valve provided in the one application liquid supply line is in the fourth state, the first valve provided in the other application liquid supply line aligned with the one application liquid supply line is in the second state, and the second valve provided in the other application liquid supply line is in the third state,
a fifth supply amount when the first valve provided in the one application liquid supply line is in the second state, the second valve provided in the one application liquid supply line is in the third state, the first valve provided in the other application liquid supply line aligned with the one application liquid supply line is in the second state, and the second valve provided in the other application liquid supply line is in the third state, and
a sixth supply amount when the first valve provided in the one application liquid supply line is in the second state, the second valve provided in the one application liquid supply line is in the third state, the first valve provided in the other application liquid supply line aligned with the one application liquid supply line is in the first state, and the second valve provided in the other application liquid supply line is in the third state,
the third supply amount is greater than the fourth supply amount, the fourth supply amount in greater than the fifth supply amount, and the fifth supply amount is greater than the sixth supply amount.

9. An application liquid application method for applying an application liquid onto a surface of a substrate using an application liquid application apparatus, the apparatus including a support stage for the substrate to be mounted on, the support stage having a rotation mechanism, and an application liquid discharge module configured to discharge the application liquid onto the surface of the substrate mounted on the support stage along on a rotation axis of the support stage, the method comprising:
rotating and accelerating the support stage to a first rotational speed and discharging the application liquid from the application liquid discharge module onto the surface of the substrate at a first discharge rate for a period of a first time;
discharging the application liquid from the application liquid discharge module onto the surface of the substrate for a period of a second time while keeping the first rotational speed of the support stage and making a transition from the first discharge rate to a second discharge rate lower than the first discharge rate;
discharging the application liquid from the application liquid discharge module onto the surface of the substrate at the second discharge rate for a period of a third time; and
stopping discharge of the application liquid from the application liquid discharge module and stopping rotation of the support stage.

10. The method according to claim 9, wherein
the application liquid discharge module includes:
a nozzle configured to discharge the application liquid toward the surface of the substrate;
at least one application liquid supply line configured to supply the application liquid to the nozzle; and
a valve control unit,
the application liquid supply line includes:
a supply tube configured to supply the application liquid to the nozzle;
a maximum flow rate adjustment module configured to adjust a maximum flow rate of the application liquid in the supply tube;
a first valve provided in a portion of the supply tube between the maximum flow rate adjustment module and the nozzle and having a first state in which supply of the application liquid to the nozzle is interrupted in the supply tube and a second state in which the application liquid is supplied to the nozzle in the supply tube, the first state and the second state being switchable by a signal from the valve control unit; and
a second valve provided in a portion of the supply tube between the first valve and the maximum flow rate adjustment module and having a third state in which a flow rate of the application liquid in the supply tube is decreased and a fourth state in which a flow rate of the application liquid in the supply tube is maintained, the third state and the fourth state being switchable independently of the first valve by a signal from the valve control unit, and
in the discharging the application liquid from the application liquid discharge module onto the surface of the substrate for a period of the second time while making a transition from the first discharge rate to the second discharge rate lower than the first discharge rate, the discharge liquid is discharged from the nozzle while transitioning from the first discharge rate to the second discharge rate by performing switching to the first state or the second state of the first valve of the application liquid supply line or switching to the third state or the fourth state of the second valve at prescribed times by the valve control unit in the second time.
